(19) United States
(12) Patent Application Publication
(10) Pub. No.: US 2014/0061637 A1
(43) Pub. Date: Mar. 6, 2014

(54) Corrosive Resistant Electronic Components

(71) Applicant: Jason Gu, Pittsburgh, PA (US)

(72) Inventor: Jason Gu, Pittsburgh, PA (US)

(21) Appl. No.: 14/013,489

(22) Filed: Aug. 29, 2013

Related U.S. Application Data
(60) Provisional application No. 61/694,878, filed on Aug. 30, 2012.

(51) Int. Cl. H01L 29/24

(52) U.S. Cl. CPC H01L 29/24
USPC 257/43

(57) ABSTRACT

An electronic device of the type wherein a semiconductor stack is functionally supported by interconnects, electrical contacts and dielectric materials. The interconnects and electrical contacts are composed of iridium, ruthenium, zirconium, niobium, tantalum, rhodium, chromium, nickel, palladium, osmium, platinum, titanium, silver and their alloys. The dielectric materials are formed of mixtures of titanium oxide, zirconium oxide, iridium oxide, silver oxide, ruthenium oxide, and niobium oxide. An adhesion layer may be formed of ruthenium, nickel, iridium, zirconium, titanium, chromium, and alloys thereof

### CROSS-REFERENCE TO RELATED APPLICATIONS

The present application claims the benefit of priority of U.S. provisional application Ser. No. 61/694,878 filed Aug. 30, 2012, the rights of priority of which are claimed in the present application and the subject matter of which is hereby specifically incorporated by reference in its entirety.

### BACKGROUND OF INVENTION

1. Field of the Invention

The presently disclosed invention relates to improvements in electronic devices and, more particularly, electronic devices that are intended for use in highly corrosive or other severe environments.

2. Discussion of the Prior Art

In the prior art, electronic and microelectronic systems and devices encountered significant problems when used in highly corrosive or other severe environments. For example, electronic and microelectronic devices that were used in sensors and controls that were exposed to highly corrosive environments have been subject to low reliability and greatly shortened operating life. One example of such a severe environment is an environment that includes a relatively high proportion of chlorine gas. Not only is chlorine gas inherently corrosive of the materials that are included in typical electronic and microelectronic devices, but reactions between chlorine and other elements can lead to further corrosive products (hydrochloric acid, hypochlorous acid), or the generation of significant amounts of heat (formation of salts). These corrosive species and/or the heat evolved caused degradation and eventual failure of conventional materials that are used in the design and fabrication of microelectronic and electronic circuits.

Virtually all microelectronic and electronic devices have a semiconductor stack that is composed of two or more layers of semiconductor material. In addition, they have primary elements that include: (1) interconnects that provide for the transport of electrical charge from the sides of the chip into operative regions that are internal to the device, or that provide for connection between two separate electrical components that are separated by a gap; (2) dielectrics or insulators that provide for the isolation of electrical charge (dielectrics can be used for many purposes such as enabling interconnects to conduct electrical charge without electrically shorting major portions of the device); and (3) contacts to the semiconductor that support injection of electrical current into the semiconductor; In addition, adhesion layers can be included to aid the practical fabrication of the chip. FIG. 1 shows a conventional layout of such components.

In the prior art, materials that have been conventionally used in electronic devices for interconnects and contacts (e.g. copper, gold), dielectrics/insulators (e.g. silicon dioxide) and adhesion layers (e.g. titanium) have been found to be sensitive to corrosive and other extreme environments. For example, in a chlorine-containing environment, the various elements of electronic devices have been observed to fail within a period of several days or even sooner. FIG. 2 shows an optical micrograph of such an electronic device with certain components made of conventional materials, specifically titanium and silicon dioxide.

To produce electronic and microelectronic circuits and devices that are capable of reliably operating in sensors or controls (actuators, etc) that are applied in extreme environments, new materials were required. Such devices must endure the severe environment but still retain the necessary properties of the respective elements (interconnects, contacts, dielectrics/insulator, and adhesion layer) within an electronic or microelectronic system.

### SUMMARY OF THE INVENTION

In accordance with the presently disclosed invention, an electronic device of the type that includes a semiconductor stack further includes a dielectric material element, and interconnect element, and an electrical contact element. The dielectric element functions to isolate electric charge within the device. The electrical contact conducts electrical current to and from the semiconductor stack. The interconnect electrically connects an electrical contact to another element of the device or to other electrical devices. The electronic device may also include an adhesion layer that promotes the adhesion of two or more elements in the device.

Preferably, the interconnect and the electrical contact elements are made of metals that are selected from the group of iridium, ruthenium, zirconium, niobium, tantalum, rhodium, chromium, nickel, palladium, osmium, platinum, titanium, and silver. More preferably, the interconnect and electrical contact elements are made of combinations of metals of the same group with alloys that are formed from metals of that group. Most preferably, the interconnect and electrical contact elements are made of combinations of alloys of metals that are formed from alloy mixtures of that same group.

Preferably, the dielectric element is made of metal oxides that are selected from the group of titanium oxide, zirconium oxide, iridium oxide, silver oxide, ruthenium oxide, and niobium oxide. More preferably, the dielectric material includes a first oxide that is selected from the group comprising titanium oxide, zirconium oxide, iridium oxide, silver oxide, ruthenium oxide, and niobium oxide. The first oxide is then combined with mixtures of two or more other oxides selected from the group. The first oxide and be applied either first or in combination with the oxide mixture by sputtering techniques.

Also preferably, the adhesion layer is made of material selected from the group comprising ruthenium, nickel, iridium, zirconium, titanium, chromium, and alloys thereof The adhesion layer may be composed of a combination of one material selected from the group of ruthenium, nickel, iridium, zirconium, titanium, chromium, and alloys thereof in the range of 10% to 90% with another material selected from the same group.

Other objects, advantages and features of the presently disclosed invention will become apparent to those skilled in the art as a description of a presently preferred embodiment thereof proceeds.

### BRIEF DESCRIPTION OF THE DRAWINGS

The presently disclosed invention is disclosed in connection with a presently preferred embodiment of the same that is explained in connection with the appended drawings in which:

FIG. 1 is a schematic cross-section of representative elements of a conventional electronic device that includes interconnects, a dielectric/insulator, a contact, and an adhesion layer illustrating their location relative to a typical semiconductor stack.

FIG. 2 shows an electronic device made of conventional materials known in the prior art after the device was exposed to a corrosive environment for two weeks.

FIG. 3 shows a test structure that was used to test the corrosion resistance of interconnects that are disclosed herein.

FIG. 4 is a characteristic data curve from test structures that are shown in FIG. 3.

FIG. 5 is a characteristic micrograph of the test structure shown in FIG. 4 after the device was exposed to wet chlorine.

FIG. 6 is a characteristic data curve from test structures shown in FIG. 3 constructed according to the invention herein disclosed.

FIG. 7 shows titanium metal that is covered with titanium dioxide deposited using atomic layer deposition.

FIG. 8 shows delamination of a microchip after exposure to a corrosive environment.

FIG. 9 shows a micrograph of a device with metallic interconnects, dielectrics, and adhesion layers according to the presently disclosed invention where the device has been exposed to a wet chlorine environment.

### DESCRIPTION OF A PRESENTLY PREFERRED EMBODIMENT

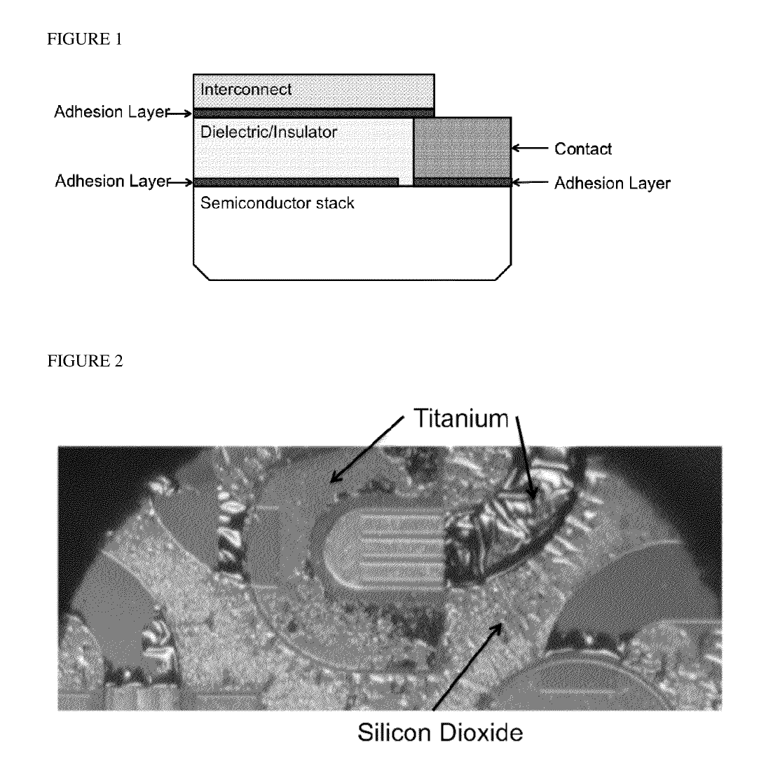

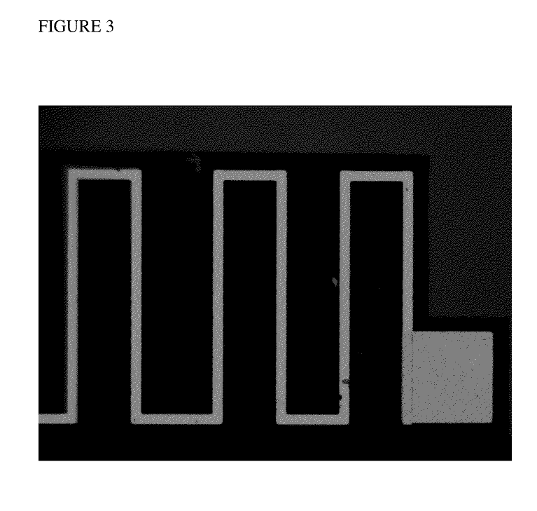

In the presently disclosed embodiment, interconnect, contact, dielectric/insulator, and adhesion layer materials are designed for improved performance and longevity in a corrosive environment such as a high-chlorine environment. FIG. 2 shows an electronic device with elements that include interconnects, contacts, dielectric/insulators, and adhesion layers (titanium). In the device of FIG. 2, the elements are composed of conventional materials. The interconnects and contacts can be copper, gold, platinum, or palladium; the dielectric/insulators can be silicon dioxide or hafnium dioxide; and the adhesion layers can be titanium. The device shown in FIG. 2 was exposed to a chlorine-containing environment for a period of two weeks. That exposure resulted in significant chemical degradation and delamination of the titanium. Cracking of the silicon dioxide also occurred. The device was no longer operational after only 1 week.

The test structures shown in FIG. 3 were fabricated using conventional lithography techniques to better evaluate the corrosion resistance of interconnects. The structures used gold, copper, platinum, and palladium. They all degraded and failed within an hour of initial exposure to wet chlorine.

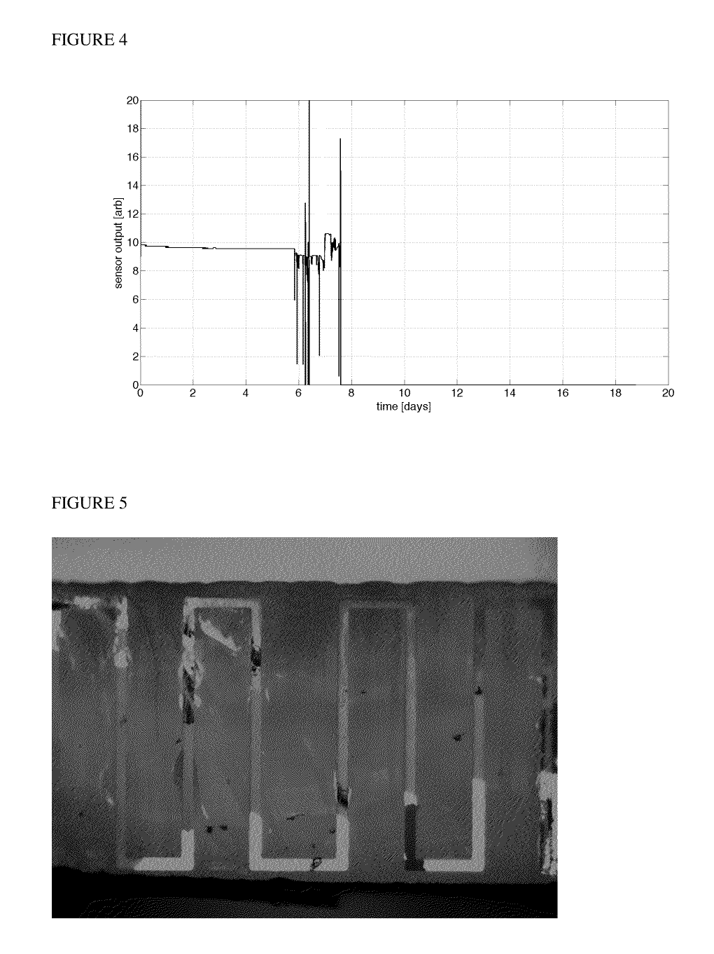

In contrast to such conventional materials that are used in electronic and microelectronic devices as shown in FIG. 3, the component materials for interconnects and contacts that are disclosed herein include pure forms and alloys of iridium, tantalum, ruthenium, zirconium, chromium, rhodium, chromium, nickel, palladium, osmium, platinum, titanium, silver and niobium. FIG. 4 is a characteristic data curve for test structures constructed of pure phases of these metals when exposed to wet chlorine. After 6 days of stability, degradation of the metallic interconnects caused significant noise in the signal due. After another day and a half, the test structure completely failed. A characteristic micrograph of the failed structure is shown in FIG. 5 which shows that preferential etching of the metallic line has occurred and that there has been complete removal of the metallic line in many locations.

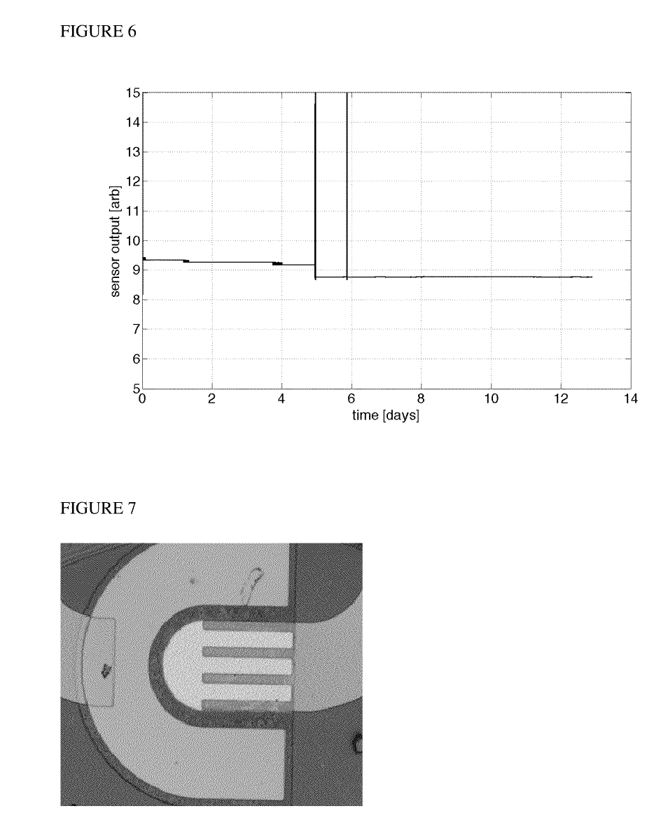

While the elements of the device that is disclosed herein have considerable stability when the elements are composed of pure metals, alloys of those metals were found to demonstrate even greater stability for still longer periods of time. FIG. 6 shows a characteristic data curve from test structures of the type shown in FIG. 3, except that the structure in FIG. 6 is constructed with mixed alloys of the metals iridium, tantalum, ruthenium, zirconium, chromium and niobium. Other alloys of the group of iridium, tantalum, ruthenium, zirconium, chromium, rhodium, chromium, nickel, palladium, osmium, platinum, titanium, silver and niobium also could have been used.

Test structure specimens that incorporated a wide range of combinations of these metals and at various relative concentrations were tested and found to afford improved performance in comparison to compositions that were known in the prior art. It was found that most preferred were interconnects deposited with iridium and ruthenium ratios of 4:1, iridium and rhodium ratios of 4:1, iridium and tantalum ratios of 10:1, chromium and ruthenium ratios of 1:1, and tantalum and ruthenium ratios of 1:5. The most preferred tertiary composition was a mixture of iridium, ruthenium, rhodium, and tantalum at ratios of 4:1:1:1. All samples were annealed to achieve their equilibrium phases.

The electrical contact and the interconnect can be constructed of multiple layers of metals that are selected from the group of iridium, tantalum, ruthenium, zirconium, chromium, rhodium, chromium, nickel, palladium, osmium, platinum, titanium, silver and niobium. The contacts and interconnects can be fabricated from the selected metals by deposition followed by annealing the metallic layers. In some cases, the electrical contacts and interconnects includes multiple layers of metals, sometimes having as many as ten layers of metals. The electrical contacts and interconnects can also be made from alloys of the group of iridium, tantalum, ruthenium, zirconium, chromium, rhodium, chromium, nickel, palladium, osmium, platinum, titanium, silver and niobium. For some applications, it is preferred that that alloy is composed by combining less than 50% of one metal selected from the group of iridium, tantalum, ruthenium, zirconium, chromium, rhodium, chromium, nickel, palladium, osmium, platinum, titanium, silver and niobium into one or more other metals that are also selected from the same group. In other applications, it has been found that combining less than 35% of one metal selected from the group of iridium, tantalum, ruthenium, zirconium, chromium, rhodium, chromium, nickel, palladium, osmium, platinum, titanium, silver and niobium into one or more other metals that are also selected from the same group is more preferred. In still other circumstances, the one metal selected from the same group for combination into one or more other metals of that group is in an amount of less than 20% or even less than 10%.

Novel dielectric/insulator materials that are herein disclosed include pure or mixed oxides of zirconium, titanium, iridium, silver, ruthenium, niobium and tantalum. Preferably, such dielectric/insulator materials are made of a first oxide that is selected from the group of titanium oxide, zirconium oxide, iridium oxide, silver oxide, ruthenium oxide, tantalum oxide, and niobium oxide. The selected first oxide is then combined with mixtures of two or more other oxides that are selected from the same group. Preferably, the mixture of two or more other oxides is prepared by mixing an oxide of one material from the group in the range of 10% to 90% into the oxide of another material from the group. More preferably, an oxide of one material from the group in the range of 25% to 75% is mixed into the oxide of another material from the group.

In some instances, the first oxide is applied by sputtering in an over-pressure environment of oxygen or by sputtering using an oxide target. Alternatively, the first oxide can be combined with the mixture of two or more other oxides and the combination then applied by sputtering in an over-pressure environment of oxygen or by sputtering using an oxide target. When sputtering in an over-pressure oxygen environment is used, the oxygen environment is preferably in the range of 10% to 100% oxygen.

FIG. 7 is an image of titanium metal covered with titanium dioxide deposited using atomic layer deposition. If the titanium metal were uncovered, it would rapidly corrode in the chlorine environment. However, in the specimen of FIG. 7, the underlying thin-film titanium was untouched after two months of exposure to the chlorine environment.

Thermodynamic computations support that these materials are stable. Interconnects that are fabricated using alloys and pure forms of the above listed materials were exposed to a chlorine-containing environment for periods of over eight months without significant degradation of electrical conductivity. In the same manner, the above listed insulators continued to block charge injection after exposure to a chlorine-containing environment for periods of over eight months.

Furthermore, prior art adhesion layers (e.g. titanium) are known to be prone to chemical attack. They do not prevent such delamination of two layers due to preferential attack at the interfaces of the layers. However, adhesion layers that are composed of the pure form or alloys of ruthenium, nickel, iridium, titanium, chromium and zirconium promote stronger interfaces and show no signs of chemical attack. In some cases, it is preferred that the adhesion layer is formed of alloys of ruthenium, nickel, iridium, titanium, chromium and zirconium by combining one material selected from that group in the range of 10% to 90% with another material selected from the same group. Also, the alloys may be formed by depositing one member of the group on at least one other member of said group to form a stack and thereafter annealing the stack. In certain cases, the overall thickness of the adhesion layer may be in the range of 0.5 nm to 20 nm. In other applications, the overall thickness of the adhesion layer may be in the range of 0.1 nm (nanometers) to 5 nm. In still other circumstances, the overall thickness may be in the range of 0.25 nm to 3 nm.

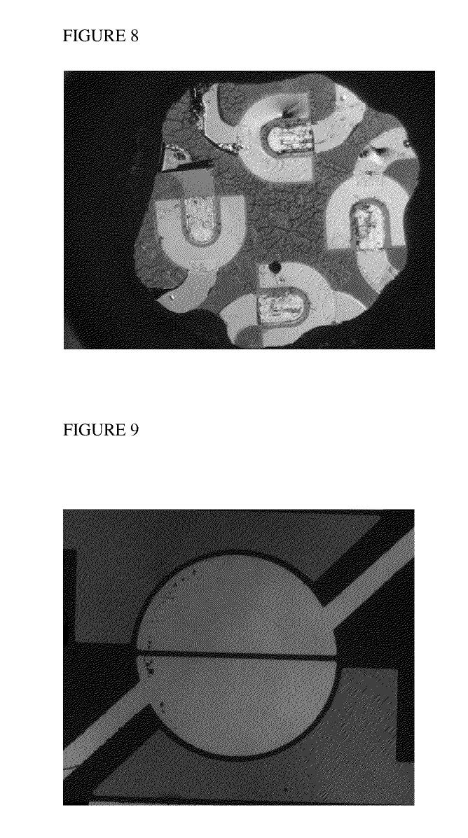

FIG. 8 shows an image of the delaminated metals, while FIG. 9 shows a micrograph of a device in which the metallic interconnects, dielectrics, and adhesion elements are composed of the pure form or alloys of ruthenium, nickel, and zirconium. In the device of FIG. 9, no significant loss of material is observed after two months of exposure to wet chlorine.

The scope of the presently disclosed invention is not limited to the forgoing presently preferred embodiment. As will be apparent to those skilled in the art, the disclosed invention can be otherwise variously embodied within the scope of the following claims.

I claim:

1. In an electronic device having a semiconductor stack and including at least one of a dielectric material element that isolates electrical charge, an electrical contact element for conducting electrical current to and from the semiconductor stack, and an interconnect element that electrically connects the electrical contact to at least one other element of the electronic device or to other electronic devices, at least one of the electrical contact and the interconnect being selected from the group comprising iridium, ruthenium, zirconium, niobium, tantalum, rhodium, chromium, nickel, palladium, osmium, platinum, titanium, silver and alloys thereof.

2. The electronic device of claim 1 wherein at least one of the electrical contact and the interconnect is comprised of multiple layers of metals that are selected from the group of claim 1 and fabricated by deposition followed by annealing the metallic layers.

3. The electronic device of claim 2 wherein said multiple layers of metals comprises one to ten layers of metals.

4. The electronic device of claim 1 wherein at least one of the electrical contact and the interconnect comprises an alloy that is made by alloying less than 35% of one metal selected from the group of claim 1 into one or more other metals that are also selected from the group of claim 1.

5. The electronic device of claim 1 wherein at least one of the electrical contact and the interconnect comprises an alloy that is made by alloying less than 20% of one metal selected from the group of claim 1 into one or more other metals that are also selected from the group of claim 1.

6. The electronic device of claim 1 wherein at least one of the electrical contact and the interconnect comprises an alloy that is made by alloying less than 50% of one metal selected from the group of claim 1 into one or more other metals that are also selected from the group of claim 1.

7. The electronic device of claim 1 wherein at least one of the electrical contact and the interconnect comprises an alloy that is made by alloying less than 10% of one metal selected from the group of claim 1 into one or more other metals that are also selected from the group of claim 1.

8. In an electronic device having a semiconductor stack and including at least one of a dielectric material element that isolates electrical charge, an electrical contact element for conducting electrical current to and from the semiconductor stack, and an interconnect element that electrically connects the electrical contact to other elements of the electronic device or other electronic devices, said dielectric material including a first oxide that is selected from the group comprising titanium oxide, zirconium oxide, iridium oxide, silver oxide, ruthenium oxide, and niobium oxide, said first oxide being combined with mixtures of two or more other oxides that are also selected from the group comprising titanium oxide, zirconium oxide, tantalum oxide, iridium oxide, silver oxide, ruthenium oxide, and niobium oxide.

9. The dielectric material of claim 8 wherein said first oxide is applied by sputtering in an over-pressure environment of oxygen.

10. The dielectric material of claim 8 wherein said first oxide and said two or more other oxides are combined and then applied by sputtering in an over-pressure environment of oxygen.

11. The dielectric material of claim 8 wherein said first oxide is applied by sputtering using an oxide target.

12. The dielectric material of claim 8 wherein said first oxide and two or more other oxides are combined and then applied by sputtering using an oxide target.

13. The dielectric material of claim 9 wherein said oxygen environment is in the range of 10% to 100% oxygen.

14. The dielectric material of claim 10 wherein said mixture of two or more other oxides comprises an oxide of one material in the range of 10% to 90% that is mixed into another oxide.

15. The dielectric material of claim 10 wherein said mixture of two or more other oxides comprises an oxide of one material in the range of 25% to 75% that is mixed into another oxide.

16. In an electronic device having a semiconductor stack, and including at least one of a dielectric material element that isolates electrical charge, an electrical contact element for conducting electrical current to and from the semiconductor stack, and an interconnect element that electrically connects the electrical contact to other elements of the electronic device or to other electronic devices, an adhesion layer that promotes sticking together of at least two elements of said electronics device, said adhesion layer being material selected from the group comprising ruthenium, nickel, iridium, zirconium, titanium, chromium, and alloys thereof.

17. The adhesion layer of claim 16 wherein said alloys are formed by combining one material selected from the group of claim 16 in the range of 10% to 90% with another material selected from the group of claim 16.

18. The adhesion layer of claim 16 wherein said alloys are formed by depositing one member of the group on at least one other member of said group to form a stack and thereafter annealing the stack.

19. The adhesion layer of claim 16 wherein the thickness of said adhesion layer is in the range of 0.5 nm to 20 nm.

20. The adhesion layer of claim 16 wherein the thickness of said adhesion layer is in the range of 0.1 nm to 5 nm.

21. The adhesion layer of claim 16 wherein the thickness of said adhesion layer is in the range of 0.25 nm to 3 nm.
